(19) United States
(12) Patent Application Publication
(10) Pub. No.: US 2023/0268720 A1
(43) Pub. Date: Aug. 24, 2023

(54) LASER DEVICE

(71) Applicant: NICHIA CORPORATION, Anan-shi (JP)

(72) Inventors: Tetsushi TAKANO, Kyoto-shi (JP); Masanori OKADA, Yokohama-shi (JP)

(73) Assignee: NICHIA CORPORATION, Anan-shi (JP)

(21) Appl. No.: 18/171,432

(22) Filed: Feb. 20, 2023

(30) Foreign Application Priority Data
Feb. 21, 2022 (JP) 2022-024722
Jan. 17, 2023 (JP) 2023-004863

(51) Int. Cl. H01S 5/14; H01S 5/10; H01S 5/343; H01S 5/04; H01S 5/024; H01S 5/028

(52) U.S. Cl. CPC H01S 5/143; H01S 5/1053; H01S 5/34346; H01S 5/041; H01S 5/02469; H01S 5/34333; H01S 5/028

(57) ABSTRACT

The laser device includes a first mirror and a second mirror forming a resonator, a gain medium disposed between the first mirror and the second mirror and having a light emitting surface, an antireflection film provided on the light emitting surface of the gain medium, at least one optical element disposed between the gain medium and the second mirror, and a diffraction grating disposed between the optical element and the second mirror. The gain medium is a semiconductor layered body including an active layer and having a varying gain distribution in at least a first direction within the light emitting surface, and includes no waveguide.

### CROSS-REFERENCE TO RELATED APPLICATION

This application claims priority to Japanese Patent Application No. 2022-024722, filed on Feb. 21, 2022, and Japanese Patent Application No. 2023-004863, filed on Jan. 17, 2023, the disclosures of which are hereby incorporated by reference in their entireties.

### BACKGROUND

The present disclosure relates to a laser device.

A laser device that emits a high-power laser beam can be used for processing such as cutting, drilling, and marking, for example. As a technique for producing a high-power laser beam, a wavelength beam combining (WBC) technique is known, in which a plurality of laser beams having different wavelengths are coaxially combined with each other by a diffraction grating. Japanese Patent Publication No. 2017-539083 discloses an example of a laser device that combines a plurality of laser beams emitted from a laser diode (LD) bar and having different wavelengths, and emits a high-power laser beam.

### SUMMARY

There is a need for a laser device in which optical damage to a light emitting surface of a gain medium can be reduced.

According to one embodiment of the present disclosure, a laser device includes a first mirror and a second mirror forming a resonator, a gain medium disposed between the first mirror and the second mirror and including a light emitting surface, an antireflection film provided on the light emitting surface of the gain medium, at least one optical element disposed between the gain medium and the second mirror, and a diffraction grating disposed between the optical element and the second mirror. The gain medium is a semiconductor layered body including an active layer and having a varying gain distribution in at least one direction within the light emitting surface, and includes no waveguide.

According to another embodiment of the present disclosure, a laser device includes a first mirror and a second mirror forming a resonator, a gain medium having a light emitting surface and disposed between the first mirror and the second mirror, an antireflection film provided on the light emitting surface of the gain medium, an optical element disposed between the gain medium and the second mirror, and a diffraction grating disposed between the optical element and the second mirror. The gain medium is a semiconductor layered body comprising an active layer and having a varying gain distribution in at least one direction within the light emitting surface. The gain medium is a surface emitting light source.

Laser devices according to certain embodiments of the present disclosure can allow optical damage to a light emitting surface of a gain medium to be reduced.

### BRIEF DESCRIPTION OF DRAWINGS

FIG. 1A is a top view schematically illustrating a configuration of a laser device according to a first embodiment.

FIG. 1B is a cross-sectional view taken along line IB-IB illustrated in FIG. 1A.

FIG. 2 is a top view schematically illustrating a state in which five light beams are coaxially combined by a diffraction grating.

FIG. 3A is a top view schematically illustrating a configuration of a first modified example of the laser device according to the first embodiment.

FIG. 3B is a cross-sectional view taken along line IIIB-IIIB illustrated in FIG. 3A.

FIG. 3C is a top view schematically illustrating a configuration of a second modified example of the laser device according to the first embodiment.

FIG. 3D is a top view schematically illustrating a configuration of a third modified example of the laser device according to the first embodiment.

FIG. 3E is a top view schematically illustrating a configuration of a fourth modified example of the laser device according to the first embodiment.

FIG. 4 is a top view schematically illustrating a configuration of a laser device according to a second embodiment.

FIG. 5 is a view schematically illustrating a state in which five light beams are coaxially combined by a first diffraction grating and a second diffraction grating.

FIG. 6A is a top view schematically illustrating a configuration of a fifth modified example of the laser device according to the second embodiment.

FIG. 6B is a top view schematically illustrating a configuration of a sixth modified example of the laser device according to the second embodiment.

FIG. 6C is a top view schematically illustrating a configuration of a seventh modified example of the laser device according to the second embodiment.

FIG. 7A is a top view schematically illustrating a first example of optically exciting a gain medium.

FIG. 7B is a top view schematically illustrating a second example of optically exciting the gain medium.

FIG. 7C is a top view schematically illustrating a third example of optically exciting the gain medium.

### DETAILED DESCRIPTION

A laser device according to embodiments of the present disclosure will be described below in detail with reference to the drawings. Parts having the same reference numerals appearing in the plurality of drawings indicate identical or equivalent parts.

The embodiments described below embody the technical idea of the present invention, but the present invention is not limited to the described embodiments. Furthermore, the description of the dimensions, materials, shapes, relative arrangements, and the like of components are intended to be illustrative rather than limiting the scope of the present invention. The size, positional relationship, and the like of the members illustrated in the drawings may be exaggerated in order to facilitate understanding and the like.

In the present specification, a diameter of a beam is referred to as a “beam diameter.” The beam diameter is defined by the size of a region having a light intensity of 1/e² or more with respect to a light intensity at a beam center, where “e” is the Napier number.

According to one embodiment of the present disclosure, a laser device includes a first mirror and a second mirror forming a resonator, a gain medium having a light emitting surface and disposed between the first mirror and the second mirror, an antireflection film provided on the light emitting surface of the gain medium, at least one optical element disposed between the gain medium and the second mirror, and a diffraction grating disposed between the optical element and the second mirror. The gain medium is a semiconductor layered body including an active layer and having a varying gain distribution in at least one direction within the light emitting surface, and includes no waveguide.

In the laser device of the present disclosure configured as described above, optical damage to the light emitting surface of the gain medium can be reduced.

### First Embodiment

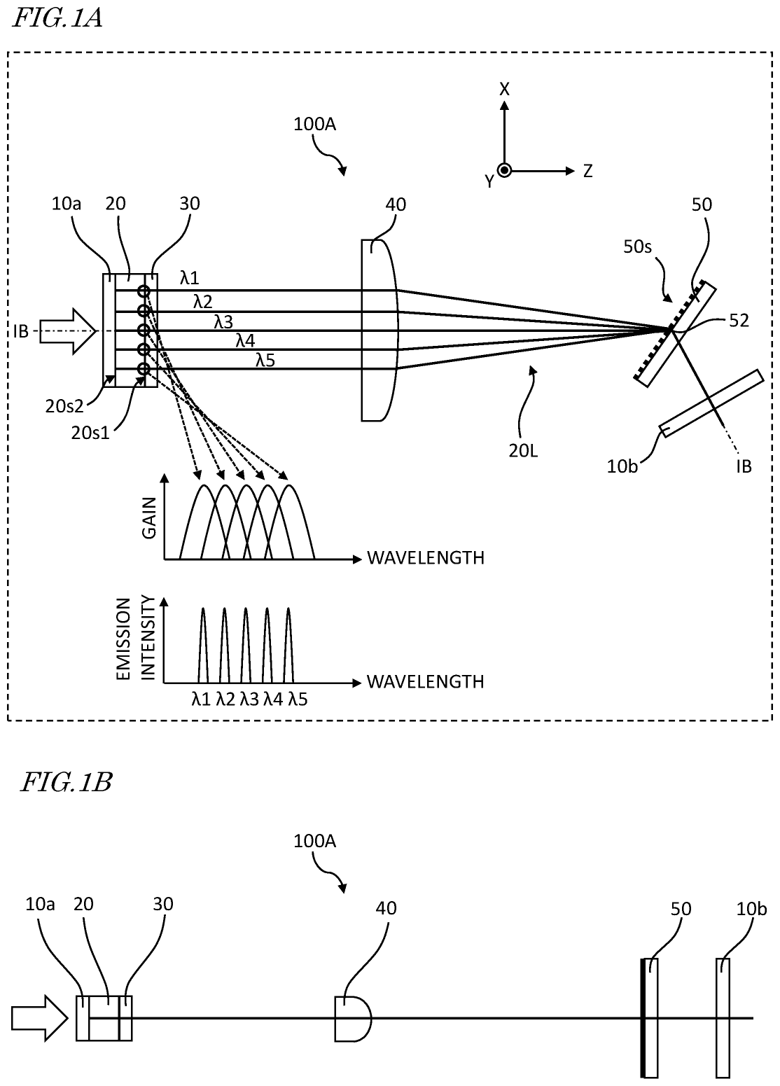

First, an example configuration of a laser device in which optical damage to a light emitting surface of a gain medium can be reduced, according to a first embodiment of the present disclosure, will be described with reference to FIGS. 1A and 1B.

Configuration of Laser Device

FIG. 1A is a top view schematically illustrating the configuration of a laser device according to the first embodiment of the present disclosure. FIG. 1B is a cross-sectional view taken along line IB-IB illustrated in FIG. 1A. An X-axis, a Y-axis, and a Z-axis that are orthogonal to one another in the drawings are schematically shown for reference. The direction of an arrow on the X-axis is a +X direction, and an opposite direction of the +X direction is a −X direction. When the ±X directions are not distinguished, they are simply referred to as X directions. The same applies to a Y direction and a Z direction.

A laser device 100A illustrated in FIGS. 1A and 1B includes a first mirror 10a and a second mirror 10b, which are planar mirrors forming a resonator, and a gain medium 20 disposed between the first mirror 10a and the second mirror 10b. The gain medium 20 includes a light emitting surface 20s1 and a back surface 20s2 located on the opposite side from the light emitting surface 20s1. Each of the light emitting surfaces 20s1 and the back surface 20s2 is a plane parallel to an XY plane. For example, the first mirror 10a can be provided on the back surface 20s2 of the gain medium 20. The gain medium 20 includes no waveguide. Thus, light is not confined in the gain medium 20. That is, for example, the gain medium 20 has a configuration in which light is not confined in a lateral direction with respect to the light emitting surface 20s1. It can be confirmed as follows that the gain medium 20 includes no waveguide. That is, it is simply confirmed that light emitted from the gain medium 20 is not a laser beam when the gain medium 20 is excited in a state in which the first mirror and the second mirror are removed. This can be determined, for example, from the difference in behavior such as a beam diameter of light when the light emitted from the gain medium 20 is condensed by a lens. Providing the gain medium 20 is excited with the first mirror 10a and the second mirror 10b removed from the laser device 100A, an M² factor, which indicates quality of laser beam, can be, for example, 1000 or more. When the value M² factor is great enough, light emitted from the gain medium 20 cannot be regarded as a laser light.

The laser device 100A illustrated in FIGS. 1A and 1B further includes an antireflection film 30, at least one optical element 40, and a diffraction grating 50 between the gain medium 20 and the second mirror 10b, in a sequence of proximity to the gain medium 20. The antireflection film 30 is provided on the light emitting surface 20s1 of the gain medium 20. The optical element 40 is disposed between the gain medium 20 and the second mirror 10b. The diffraction grating 50 is disposed between the optical element 40 and the second mirror 10b. In FIGS. 1A and 1B, the optical element 40 are illustrated as a lens. The diffraction grating 50 includes a surface 50s, and a plurality of diffraction grooves extending along the Y direction are periodically provided on the surface 50s. An angle formed by the surface 50s of the diffraction grating 50 and a plurality of incident light rays 20L may be in a range from 30° to 60°, for example. The diffraction grating 50 is preferably a transmissive diffraction grating. The transmissive diffraction grating has a higher diffraction efficiency than a reflective diffraction grating. The second mirror 10b is positioned so as to receive light diffracted and transmitted by the diffraction grating 50. However, the diffraction grating 50 does not necessarily have to be a transmissive diffraction grating, and may be a reflective diffraction grating. In such a case, the second mirror 10b is positioned so as to receive light diffracted and reflected by the diffraction grating 50.

In the laser device 100A illustrated in FIGS. 1A and 1B, a +Z direction is the normal direction of the light emitting surface 20s1 of the gain medium 20. The Y direction is a direction parallel to a direction in which the grooves of the diffraction grating 50 extend. The X direction is a direction orthogonal to the Z direction and the Y direction. The X direction may be, for example, a direction in which a gain varies in the light emitting surface 20s1 of the gain medium 20.

Gain Distribution in Gain Medium 20

The gain medium 20 is a semiconductor layered body including an active layer and having a varying gain distribution in at least one direction within the light emitting surface 20s1. A stacking direction is parallel to the Z direction. The gain medium 20 illustrated in FIGS. 1A and 1B has a rectangular parallelepiped shape that is wider in the X direction than in the Y direction. The gain medium 20 may have a disc shape that is widened along the XY plane. When the gain medium 20 has a rectangular parallelepiped shape, a semiconductor chip having a rectangular parallelepiped shape may be cut out from a semiconductor wafer as the gain medium 20. The semiconductor wafer has a varying gain distribution; for example, a gain varies outward from the center of the semiconductor wafer. By cutting the semiconductor chip along the varying gain distribution of the semiconductor wafer, the semiconductor chip can be suitably used as the gain medium 20. Note that, as the gain medium 20, a semiconductor wafer may be used as is, or a semiconductor wafer having its peripheral edge portion cut off may be used. The gain medium 20 can include an active layer directly formed on the substrate. The active layer does not have to be interposed between an n-type semiconductor layer and a p-type semiconductor layer.

In the first embodiment, the gain medium 20 has a varying gain distribution that varies in the X direction of the light emitting surface 20s1. FIG. 1A illustrates a gain spectrum (relationship between gain and wavelength) in five representative locations (round marks) on the light emitting surface 20s1 of the gain medium 20. In the example illustrated in FIG. 1A, a broad gain peak shifts to a short wavelength side along the +X direction. A wavelength at which the gain is maximized in the gain medium 20 may be varied along one direction within the light emitting surface 20s1 to become shorter from one end to the other end of the gain medium 20, and may preferably monotonically varied. It is sufficient that the peak wavelength of the gain tends to become shorter along the +X direction as a whole, and does not need to become shorter monotonically. With the varying gain distribution having the gradient as described above, the gain medium 20 can be used as a surface emitting light source, and the light density of the light emitting surface 20s1 of the gain medium 20 can be reduced while combining wavelength beams. The above varying gain distribution in the gain medium 20 can be achieved by changing, for example, temperature and/or gas conditions during fabrication of a semiconductor wafer, for example. Note that the presence or absence of the above-described varying gain distribution in the gain medium 20 can be confirmed by examining the distribution of emission wavelengths on the light emitting surface 20s1 of the gain medium 20 by photoluminescence measurement, for example.

The active layer may be formed from a nitride semiconductor containing, for example, indium and/or aluminum. The active layer may have a multiple quantum well structure including a plurality of well layers and a plurality of barrier layers. The well layer may be formed from, for example, GaN, InGaN, or AlGaN, and the barrier layer may be formed from, for example, AlGaN or GaN.

The content of the indium and/or aluminum in the nitride semiconductor varies in the light emitting surface 20s1. For example, the content of the indium and/or aluminum in the nitride semiconductor varies along the X direction on the light emitting surface 20s1. The range of gain that varies along the X direction falls within a range from 300 nm to 650 nm, for example. The range of the peak wavelength of the gain may have a wavelength width in a range from 10 nm to 100 nm, for example. The peak of the gain at discretionary location in the gain medium 20 has a peak width in a range from 10 nm to 50 nm, for example. In an example, the gain of the gain medium 20 in the X direction may be 450 nm at one end of the gain medium 20 and 500 nm at the other end thereof. That is, the gain width may be in a range from 450 nm to 500 nm. Note that when the range of the peak wavelength of the gain is within a range of wavelengths longer than 650 nm, the active layer may be formed from, for example, an arsenide semiconductor or a phosphide semiconductor.

The gain medium 20 may have the dimensions as described below, for example. When the gain medium 20 has a rectangular parallelepiped shape, the dimension in the direction in which the gain of the gain medium 20 varies (for example, the X direction) may be, for example, in a range from 1 cm to 10 cm or from 1 cm to 5 cm, the dimension in the direction in which the gain does not vary (for example, the Y direction) may be, for example, in a range from 10 μm to 1 mm, and the dimension in the thickness direction (Z direction) may be, for example, from 10 μm to 1 mm. When the gain medium 20 has a disk shape, the diameter may be in a range from 1 cm to 10 cm or from 1 cm to 5 cm, for example, and the dimension in the Z direction may be in a range from 10 μm to 1 mm, for example.

The refractive index of the gain medium 20 is continuous and smooth in the X direction of the light emitting surface 20s1, and may be monotonically varied. However, the gain medium 20 may have, for example, a recess in a peripheral region of the light emitting surface 20s1, and the refractive index of the gain medium 20 may change steeply at an interface of the recess. The recess may be filled with another member. The area ratio of the recess to the total area of the light emitting surface 20s1 of the gain medium 20 may be 10% or less, or 5% or less, for example. Furthermore, from the viewpoint of stably resonating light, an inner region surrounded by the peripheral region of the light emitting surface 20s1 of the gain medium 20 preferably has a flat surface instead of an uneven surface. The surface roughness (Ra) of the inner region may be 100 nm or less, for example.

Optical Excitation of Gain Medium 20

The hollow arrow illustrated in FIG. 1A represents excitation light that excites the gain medium 20. The excitation light may be, for example, a laser beam or LED light. The gain medium 20 is excited by the excitation light. Light emitted from the gain medium 20 is externally resonated by the first mirror 10a and the second mirror 10b, and the externally resonated light is extracted from the second mirror 10b.

The first mirror 10a transmits the excitation light with a transmittance of 80% or more, preferably 90% or more, and reflects almost 100% of the light emitted from the gain medium 20. The first mirror 10a may include, for example, a dielectric multilayer film. The dielectric multilayer film may be formed by alternately and periodically stacking two kinds of dielectrics having different refractive indices, such as SiO₂/Ta₂O₅, SiO₂/HfO₂, or TiO₂/SiO₂. The dielectric multilayer film functions as a distributed Bragg reflector, for example.

The second mirror 10b reflects a part of the light emitted from the gain medium 20, and transmits the remaining part. The reflectance of the second mirror 10b with respect to the light emitted from the gain medium 20 may be in a range from 96% to 99.5%, for example. The second mirror 10b may be formed from CaF₂, for example. Alternatively, the second mirror 10b may be a mirror in which a metal thin film is provided on a light-transmissive member such as BK7 (borosilicate crown glass) or synthetic quartz. In the present specification, transmissivity refers to that the transmittance of the light emitted from the gain medium 20 is 60% or more.

The antireflection film 30 includes a single layer or a multilayer, and allows the light emitted from the gain medium 20 to exits from the light emitting surface 20s1 of the gain medium 20 with little reflection. For example, the absorption rate of the antireflection film 30 with respect to the light emitted from the gain medium 20 may be less than 0.2%. The antireflection film 30 may be formed by alternately stacking two kinds of dielectrics having different refractive indices, such as SiO₂/Ta₂O₅, SiO₂/HfO₂, or TiO₂/SiO₂. However, the distribution of thicknesses of the dielectrics is different compared to the above-described distributed Bragg reflector.

Laser Oscillation in Resonator

The principle of generating laser oscillation in the resonator is described below. Light emitted from the gain medium 20 is collimated by the optical element 40 and incident on the diffraction grating 50. A plurality of light rays 20L passing through the diffraction grating 50 are wavelength beam combined and coaxially combined. A part of the wavelength beam-combined light is reflected by the second mirror 10b and fed back to the gain medium 20. At this time, because the light passes through the diffraction grating 50 again, the wavelength beam-combined light is diffracted to satisfy diffraction conditions for each wavelength, and is fed back to the gain medium 20. The fed-back light is reflected by the first mirror 10a and passes through the gain medium 20 again. In this way, the light is amplified by reciprocating the first mirror 10a and the second mirror 10b many times.

On the light emitting surface 20s1 of the gain medium 20, the wavelength of the fed-back light is aligned to be shorter in one direction. For example, the wavelength of the fed-back light may be aligned in the longitudinal direction of the gain medium 20. In the example illustrated in FIG. 1A, the wavelength is aligned to be shorter from one end on the −X direction side to the other end of the +X direction side. The thick lines in FIG. 1A represent five light rays emitted from five representative locations on the active layer among the plurality of light rays 20L. The wavelengths of the five light rays are λ1 to λ5, and a relationship of λ1<λ2<λ3<λ4<λ5 is established.

The gain medium 20 has a varying gain distribution in the light emitting surface 20s1, and thus is used as a surface emitting light source for wavelength beam combining. As a result, the light density can be dispersed over the entire light emitting surface 20s1 of the gain medium 20, so that optical damage to the light emitting surface 20s1 of the gain medium 20 can be reduced as compared with an end-face emitting laser element having a ridge.

In the end-face emitting laser element, light is confined in a transverse mode, and thus light density is concentrated on the laser light emission end face. This may result in optical damage on the laser light emission end face.

In contrast, the laser device 100A according to the embodiment 1 is a surface emitting light source in which light density is dispersed over the entire light emitting surface 20s1 of the gain medium 20, and light is not confined in the direction parallel to the light emitting surface 20s1. This can reduce optical damage to the light emitting surface 20s1.

Furthermore, the light density can be dispersed over the entire light emitting surface 20s1 of the gain medium 20, so that the concentration of heat on a part of the light emitting surface 20s1 of the gain medium 20 can be reduced.

The gain medium 20 is a surface emitting light source having a varying gain distribution in the light emitting surface 20s1. The wavelength of the fed-back light is included in the range of gain at each position on the light emitting surface 20s1. Consequently, the entire light emitting surface 20s1 of the gain medium 20 contributes to resonance, and wavelength beam combining is performed by the diffraction grating 50, so that the output of light extracted to the outside can be increased. The output of the light extracted to the outside may be in a range from 1 W to 100 W, for example.

The optical elements 40 are disposed to collimate each of the plurality of light rays 20L. Moreover, the optical element 40 is disposed so that light including the plurality of light rays 20L are collected in the same region 52 on the surface 50s of the diffraction grating 50. In the present specification, the collimation refers to not only making light completely parallel, but also reducing the spread of light.

The gain medium 20 is disposed so that the distance between the principal point of the optical element 40 and the light emitting surface 20s1 of the gain medium 20 is substantially equal to the focal length of the optical element 40. Consequently, the optical element 40 can collimate each of the plurality of rays 20L as described above. Moreover, the diffraction grating 50 is disposed so that the distance between the principal point of the optical element 40 and the surface 50s of the diffraction grating 50 is substantially equal to the focal length of the optical element 40. Consequently, the optical element 40 can collect the light including the plurality of light rays 20L in the same region 52 on the surface 50s of the diffraction grating 50. The focal length may be in a range from 1 cm to 20 cm, for example. In the present specification, the fact that a certain distance is substantially equal to the focal length of an optical element refers to that an absolute value of the difference between both distances is 1 mm or less.

Wavelength Beam Combining by Diffraction Grating 50

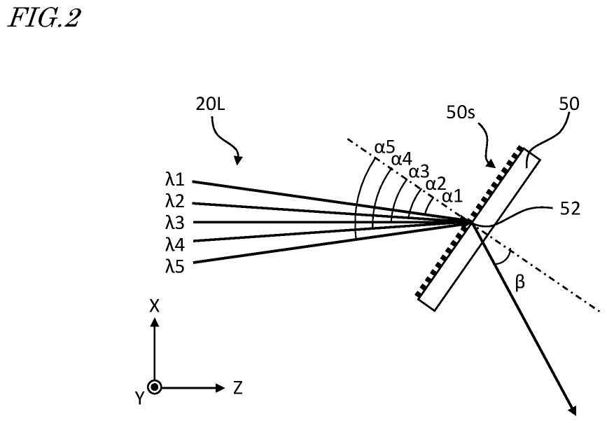

Wavelength beam combining by the diffraction grating 50 is described below with reference to FIG. 2. The diffraction grating 50 diffracts and coaxially combines the plurality of light rays 20L. FIG. 2 is a top view schematically illustrating a state in which five light rays 20L having the peak wavelengths λ1 to λ5 among the plurality of light rays 20L are coaxially combined by the diffraction grating 50. When an incident angle of a light ray having a wavelength λ is α and a diffraction angle is β with respect to a direction (one-dot chain line) perpendicular to the surface 50s of the diffraction grating 50, the following equation (1) holds:

sin(α)+sin(β)=N·m·λ (1)

In the equation (1) above, N is the quantity of diffraction grooves per 1 mm of the diffraction grating 50, and m is a diffraction order. N may be in a range from 1000/mm to 5000/mm, for example.

In the first embodiment, the diffracted transmitted light travels toward the second mirror 10b illustrated in FIG. 1A at a fixed diffraction angle β. The diffraction angle β may be in a range from 20° to 50°, for example. The shorter the peak wavelength λ, the smaller the incident angle α. Consequently, when the incident angles of the light rays having the wavelengths λ1 to λ5 are α1 to α5, respectively, the relationship of α1<α2<α3<α4<α5 holds as illustrated in FIG. 2.

Light rays having incident angles α and wavelengths λ satisfying equation (1) above are formed between the first mirror 10a and the second mirror 10b illustrated in FIG. 1A. There are countless combinations of the incident angles α and the wavelengths λ satisfying equation (1) above. Consequently, the peak wavelengths of the plurality of light rays 20L are different from each other, and are continuously and monotonically shorter along the +X direction on the light emitting surface 20s1 of the gain medium 20. FIG. 1A illustrates an emission spectrum of the five light rays emitted from the representative five locations on the light emitting surface 20s1 of the gain medium 20 (relationship between emission intensity and wavelength). Each emission peak of the light rays is narrower than the peak of gain at the corresponding location from which each light ray is emitted. The emission peak wavelength may or may not match the gain peak wavelength.

When the active layer is formed from the nitride semiconductor described above, for example, the peak wavelengths of the plurality of light rays 20L may be in a range from 350 nm to 650 nm. For example, a laser beam extracted outward from the second mirror 10b can be suitably used for processing metal such as copper. The range of the peak wavelengths of the plurality of light rays 20L may have a wavelength width in a range from 10 nm to 100 nm, for example. In an example, the range of the peak wavelengths of the plurality of light rays 20L may be in a range from 400 nm to 450 nm, and the wavelength width is in a range of 50 nm.

### Modified Example of First Embodiment

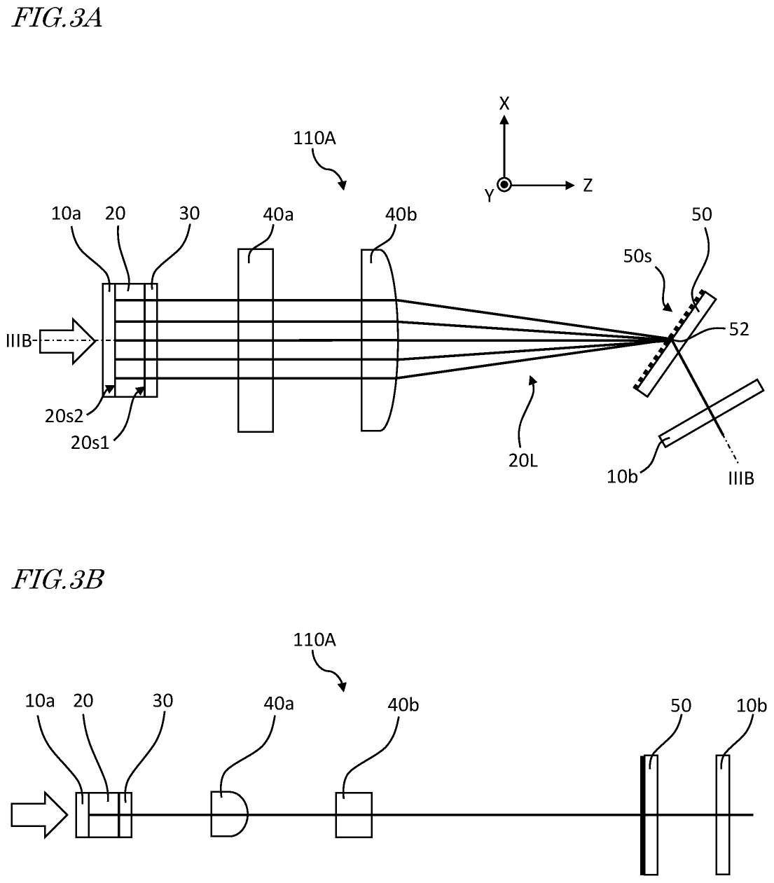

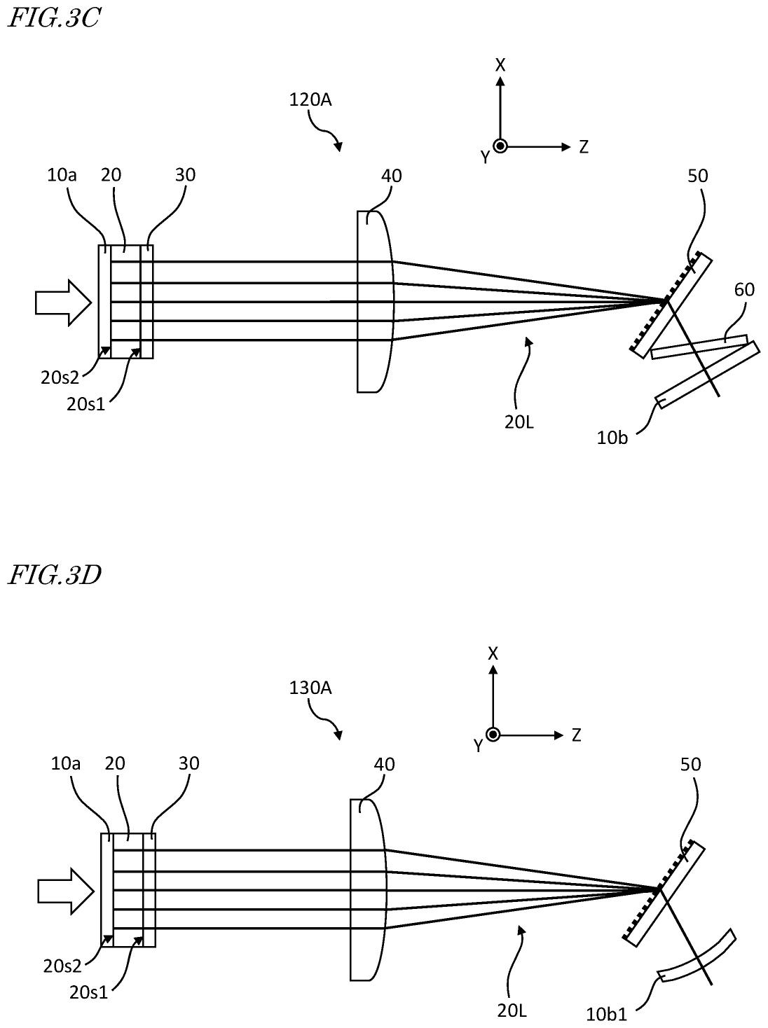

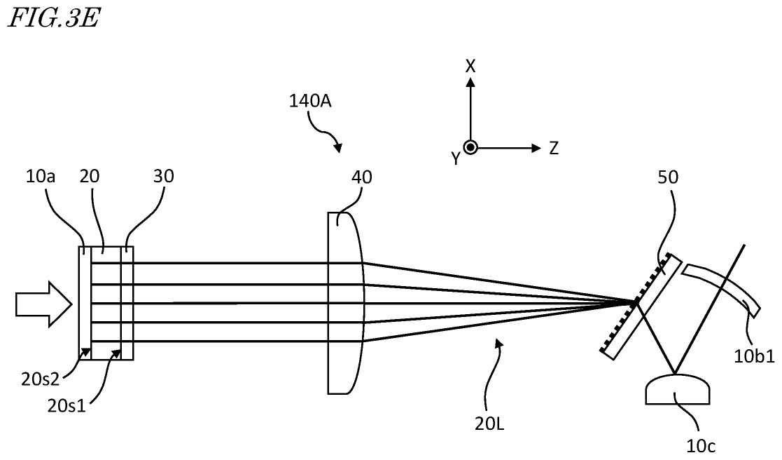

Configurations of first to fourth modified examples of the laser device 100A according to the first embodiment are described below with reference to FIGS. 3A to 3E.

### First Modified Example

FIG. 3A is a top view schematically illustrating the configuration of the first modified example of the laser device according to the first embodiment. FIG. 3B is a cross-sectional view taken along line IIIB-IIIB illustrated in FIG. 3A. A laser device 110A illustrated in FIGS. 3A and 3B is different from the laser device 100A illustrated in FIGS. 1A and 1B in that the laser device 110A includes a first lens 40a and a second lens 40b instead of the optical element 40 being as a single lens illustrated in FIGS. 1A and 1B. The first lens 40a is a fast-axis collimating (FAC) lens. The first lens 40a is, for example, a cylindrical lens extending along the X direction. The second lens 40b is a slow-axis collimating (SAC) lens. The second lens 40b is, for example, a cylindrical lens extending along the Y direction. The first lens 40a is disposed between the gain medium 20 and the second lens 40b.

The first lens 40a is disposed to collimate the plurality of light rays 20L in a fast-axis direction. The second lens 40b is disposed to collimate each of the plurality of light rays 20L in a slow-axis direction. Moreover, the second lens 40b is disposed to allow light including the plurality of light rays 20L to collect in the same region 52 on the surface 50s of the diffraction grating 50.

The gain medium 20 is disposed so that the distance between the principal point of the first lens 40a and the light emitting surface 20s1 of the gain medium 20 is substantially equal to the focal length of the first lens 40a. Consequently, the first lens 40a can collimate each of the plurality of light rays 20L as described above. Similarly, the gain medium 20 is disposed so that the distance between the principal point of the second lens 40b and the light emitting surface 20s1 of the gain medium 20 is substantially equal to the focal length of the second lens 40b. Consequently, the second lens 40b can collimate each of the plurality of light rays 20L as described above. The diffraction grating 50 is disposed so that the distance between the principal point of the second lens 40b and the surface 50s of the diffraction grating 50 is substantially equal to the focal length of the second lens 40b.

In the laser device 110A, by replacing the optical element 40 illustrated in FIGS. 1A and 1B with the first and second lenses 40a and 40b, the degree of freedom in designing the laser device 110A can be improved.

### Second Modified Example

FIG. 3C is a top view schematically illustrating the configuration of the second modified example of the laser device according to the first embodiment. A laser device 120A illustrated in FIG. 3C is different from the laser device 100A illustrated in FIG. 1A in that the laser device 120A includes a Brewster window 60 between the diffraction grating 50 and the second mirror 10b. The Brewster window 60 may be formed from a light-transmissive member such as glass, for example. The Brewster window 60 transmits P-polarized light incident at an incident angle called a Brewster angle with a transmittance of approximately 100%, and transmits S-polarized light incident at the incident angle with a transmittance in a range from approximately 30% to approximately 70%. The P-polarized light is parallel to the XZ plane and the S-polarized light is parallel to the Y direction. Due to the Brewster window 60, a Q value of the P-polarized light is much higher than a Q value of the S-polarized light in the resonator, and the plurality of light rays 20L of the P-polarized light are strongly resonated. Consequently, in the laser device 120A, a main component of a laser beam extracted outward from the second mirror 10b can be P-polarized light.

### Third Modified Example

FIG. 3D is a top view schematically illustrating the configuration of the third modified example of the laser device according to the first embodiment. A laser device 130A illustrated in FIG. 3D is different from the laser device 100A illustrated in FIG. 1A in that the laser device 130A includes a second mirror 10b1 that is a concave mirror. The gain medium 20 is disposed so that the distance between the principal point of the optical element 40 and the light emitting surface 20s1 of the gain medium 20 is shorter than the focal length of the optical element 40. The second mirror 10b1 reflects a part of light including the plurality of coaxially combined light rays 20L by the concave surface thereof, and transmits the remaining part. The material of the second mirror 10b1 may be the same as the material of the second mirror 10b illustrated in FIG. 1A.

With the arrangement as described above, when a light ray having a distribution of a beam diameter d is emitted from the gain medium 20, the beam diameter of the light ray reflected by the second mirror 10b and returning to the gain medium 20 also becomes equal to d, and as a result, the value of d is limited to one. That is, one beam diameter of a light ray is defined by the resonator, so that a single-mode oscillation is easily maintained.

Consequently, the laser device 130A can make a transverse mode a single mode while reducing optical damage to the light emitting surface 20s1 of the gain medium 20.

### Fourth Modified Example

FIG. 3E is a top view schematically illustrating the configuration of the fourth modified example of the laser device according to the first embodiment. A laser device 140A illustrated in FIG. 3E is different from the laser device 130A illustrated in FIG. 3D in that the laser device 140A includes not only the second mirror 10b1, which is a concave mirror, but also a third mirror 10c which is a convex mirror. The third mirror 10c is disposed on an optical path in the resonator, and reflects light emitted from the diffraction grating 50 toward the second mirror 10b1 with a reflectance of approximately 100%. The third mirror 10c may have, for example, a distributed Bragg reflector. The laser device 140A can make a transverse mode a single mode while reducing optical damage to the light emitting surface 20s1 of the gain medium 20.

### Second Embodiment

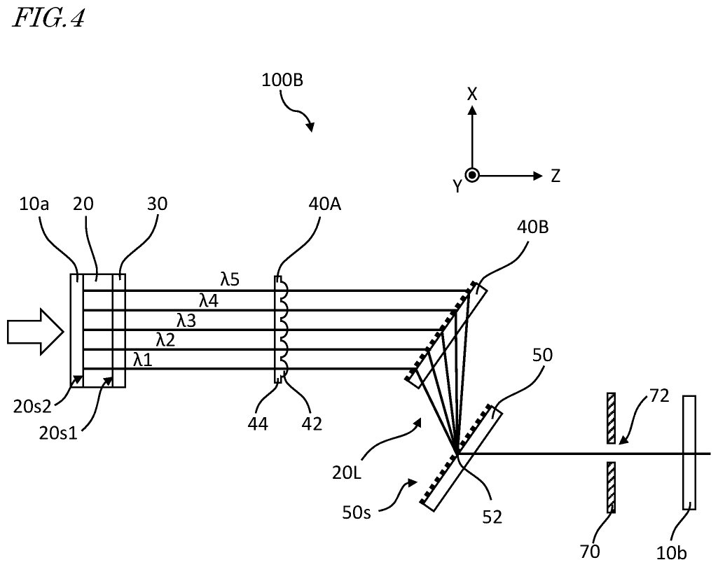

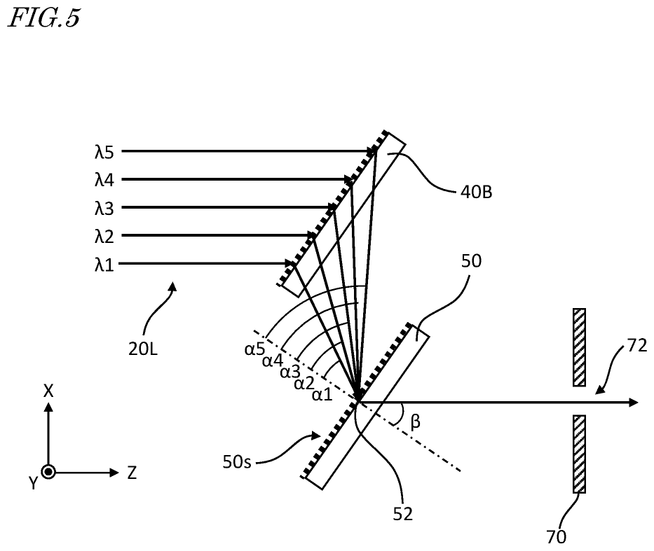

A configuration example of a laser device, according to a second embodiment of the present disclosure, which can reduce optical damage to a light emitting surface of a gain medium as in the first embodiment is described below with reference to FIG. 4. Differences from the laser device 100A according to the first embodiment are mainly described below.

Configuration of Laser Device

FIG. 4 is a top view schematically illustrating the configuration of the laser device according to the second embodiment of the present disclosure. A laser device 100B illustrated in FIG. 4 includes the first mirror 10a and the second mirror 10b forming a resonator, and the gain medium 20 disposed between the first mirror 10a and the second mirror 10b. The laser device 100B further includes, between the gain medium 20 and the second mirror 10b, the antireflection film 30, a lens array 40A, a first diffraction grating 40B, the diffraction grating 50 (referred to as a second diffraction grating 50 in the second embodiment), and an iris 70 in a sequence of proximity to the gain medium 20. As the at least one optical element 40 in the first embodiment, the lens array 40A and the first diffraction grating 40B are used.

In the gain medium 20, a gain peak wavelength is shorter from one end to the other end of the gain medium 20 along a direction opposite to the example illustrated in FIG. 1A, that is, the −X direction. The antireflection film 30 is provided on the light emitting surface 20s1 of the gain medium 20.

The lens array 40A is disposed between the gain medium 20 and the second mirror 10b. The lens array 40A includes a plurality of collimating units 42 arranged along the X direction and a link portion 44 linking the plurality of collimating units 42. Each collimating unit 42 has a curvature in the XZ plane and the YZ plane. The lens array 40A collimates the plurality of light rays 20L by the plurality of collimating units 42 on the XZ plane and the YZ plane and allows the collimated light rays 20L to exit. In the example illustrated in FIG. 4, the quantity of the plurality of collimating units 42 is five and the quantity of the plurality of light rays 20L is five. The peak wavelengths of the five light rays 20L are shorter along the −X direction on the light emitting surface 20s1 of the gain medium 20. The magnitude relationship among the peak wavelengths λ1 to λ5 illustrated in FIG. 4 is as described in the first embodiment. The lens array 40A can spatially separate the plurality of light rays 20L. That is, light emitted from the gain medium 20 is divided into a plurality of light rays 20L that are collimated by the collimating unit 42, and light that passes through the link portion 44 and is not collimated. As a consequence, it is possible to suppress a crosstalk effect in which two adjacent light rays among the plurality of light rays 20L interfere with each other and their peak wavelengths are shifted from a desired peak wavelength.

The first diffraction grating 40B and the second diffraction grating 50 are disposed parallel to each other. The first diffraction grating 40B and the second diffraction grating 50 have the same structure. A plurality of diffraction grooves of the first diffraction grating 40B and a plurality of diffraction grooves of the second diffraction grating 50 extend along the same Y direction. The cycle of the diffraction grooves of the first diffraction grating 40B is substantially the same as the cycle of the diffraction grooves of the second diffraction grating 50. Each of the first and second diffraction gratings 40B and 50 is a transmissive diffraction grating. As described above, the transmissive diffraction grating has a higher diffraction efficiency than a reflective diffraction grating. However, each of the first and second diffraction gratings 40B and 50 may be a reflective diffraction grating. In such a case, the second diffraction grating 50 is positioned so as to receive light diffracted and reflected by the first diffraction grating 40B, and the second mirror 10b is positioned so as to receive light diffracted and reflected by the second diffraction grating 50. The iris 70 has an opening 72 and is disposed between the second diffraction grating 50 and the second mirror 10b.

The first diffraction grating 40B diffracts light from the gain medium 20 to the second diffraction grating 50, and the second diffraction grating 50 further diffracts the light diffracted by the first diffraction grating 40B toward the second mirror 10b and combines the diffracted light. That is, the first diffraction grating 40B allows the plurality of light rays 20L to be incident on the same region 52 on the surface of the second diffraction grating 50 by diffraction. The second diffraction grating 50 coaxially combines, by diffraction, the plurality of light rays 20L diffracted by the first diffraction grating and allows the combined light ray to exit toward the second mirror 10b. The first diffraction grating 40B and the second diffraction grating 50 having the same structure allow the traveling direction of the light exiting the second diffraction grating 50 to be parallel to the traveling direction of the plurality of light rays 20L incident on the first diffraction grating 40B. The second mirror 10b reflects a part of the light exiting the second diffraction grating 50 and passing through the opening 72 of the iris 70 and transmits the remaining part. Only the light passing through the opening 72 of the iris 70 is resonated in the resonator, and as a result, light including the plurality of light rays 20L coaxially combined is extracted outward from the second mirror 10b. The minimum diameter of the opening 72 of the iris 70 is, for example, at least one times the beam diameter of each of the light rays 20L. The maximum diameter of the opening 72 of the iris 70 is, for example, less than twice the beam diameter of each of the light beams 20 L.

In the first embodiment, as illustrated in FIG. 1A described above, the optical element 40 collects light including the plurality of light rays 20L in the same region 52 on the surface 50s of the diffraction grating 50, and collimates each of the plurality of light rays 20L. On the other hand, in the second embodiment, as illustrated in FIG. 4, the role of the optical element 40 is shared by the lens array 40A and the first diffraction grating 40B. That is, the lens array 40A collimates each of the plurality of light rays 20L, and the first diffraction grating 40B collects light including the plurality of light rays 20L in the same region 52 on the surface 50s of the diffraction grating 50. The first diffraction grating 40B illustrated in FIG. 4 diffracts the plurality of light rays 20L to the same region 52 on the surface 50s of the second diffraction grating 50 while light collimated by the lens array 40A maintains substantially the same cross-sectional area as the cross-sectional area of light incident on the first diffraction grating 40B. Consequently, the light density in the same region 52 on the surface 50s of the second diffraction grating 50 illustrated in FIG. 4 is lower than the light density in the same region 52 on the surface 50s of the diffraction grating 50 illustrated in FIG. 1A, so that optical damage to the second diffraction grating 50 can be suppressed.

Wavelength Beam Combining by First and Second Diffraction Gratings 40B and 50 Wavelength beam combining by the first and second diffraction gratings 40B and 50 is described below with reference to FIG. 5. FIG. 5 is a view schematically illustrating a state in which the five light rays 20L having the peak wavelengths λ1 to λ5 are coaxially combined by the first and second diffraction gratings 40B and 50. Regarding the second diffraction grating 50, when an incident angle of a light ray having a peak wavelength λ is α and a diffraction angle is β, the above equation (1) holds. The diffraction angle β is fixed, and the shorter the peak wavelength λ, the smaller the incident angle α. Consequently, as illustrated in FIG. 5, a relationship of α1<α2<α3<α4<α5 is established.

However, in the example illustrated in FIG. 2 described above, the light rays 20L are incident from the −X direction side of the diffraction grating 50, whereas in the example illustrated in FIG. 5, the light rays 20L are incident from the +X direction side of the second diffraction grating 50. Consequently, in the example illustrated in FIG. 4, the peak wavelengths of the plurality of light rays 20L are shorter along the direction opposite to the example illustrated in FIG. 1A, that is, the −X direction. Also in the gain medium 20 illustrated in FIG. 4, the gain peak wavelength is monotonically shorter from one end to the other end of the gain medium 20 along the −X direction. Consequently, the peak intensities of the plurality of light rays 20L are substantially constant. Note that by shifting the position of the iris 70 in the ±X direction, the position of the opening 72 and the position of the same region 52 in the second diffraction grating 50 can also be shifted. Thus, by changing the incident angles of the plurality of light rays 20L in the second diffraction grating 50, a resonance wavelength can be changed. That is, the resonance wavelength can be selected by the position of the iris 70, so that the degree of freedom in designing the laser device 100B can be increased.

### Modified Example of Second Embodiment

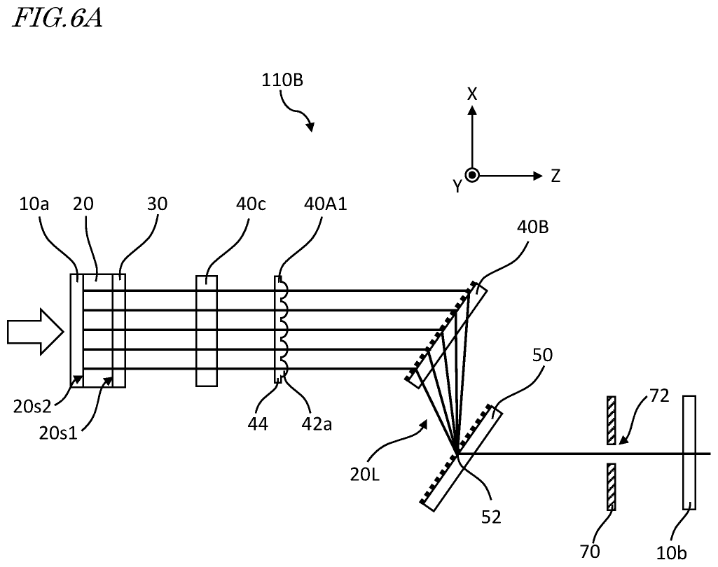

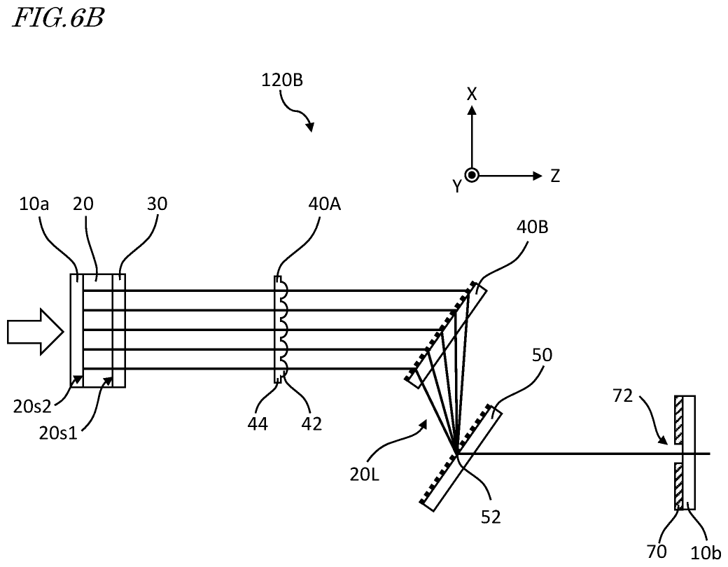

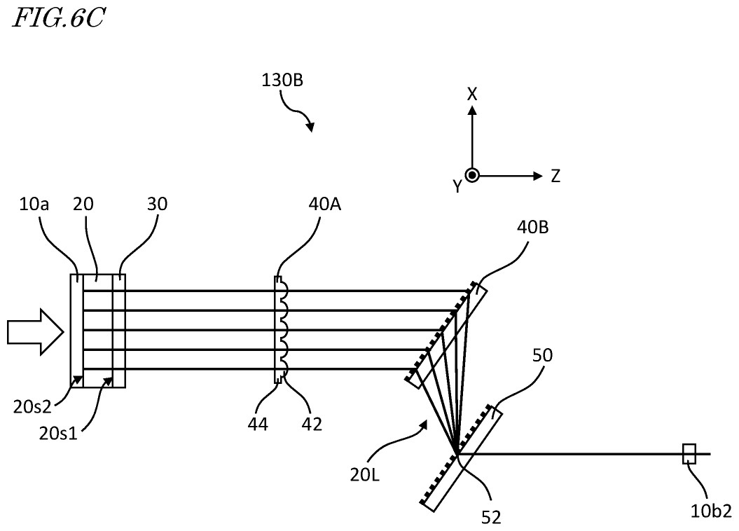

Configurations of fifth to seventh modified examples of the laser device 100B according to the second embodiment are described below with reference to FIGS. 6A to 6C. No distinction is made between the first embodiment and the second embodiment regarding the numbering of the modified examples.

### Fifth Modified Example

FIG. 6A is a top view schematically illustrating the configuration of the fifth modified example of the laser device according to the second embodiment. A laser device 110B illustrated in FIG. 6A is different from the laser device 100B illustrated in FIG. 4 in that the laser device 110B includes a lens array 40A1 and a lens 40c instead of the lens array 40A illustrated in FIG. 4. The lens array 40A1 includes a plurality of collimating units 42a and a link portion 44 that links the plurality of collimating units 42a. Each collimating unit 42a forms a SAC lens. Each collimating unit 42a is a cylindrical lens. The lens 40c functions as a FAC lens. The lens 40c is a cylindrical lens. In the laser device 110B, the lens array 40A illustrated in FIG. 4 can be replaced with the lens array 40A1 including a plurality of cylindrical lenses and the lens 40c that is a cylindrical lens. Consequently, the degree of freedom in designing the laser device 110B can be improved.

### Sixth Modified Example

FIG. 6B is a top view schematically illustrating the configuration of the sixth modified example of the laser device according to the second embodiment. A laser device 120B illustrated in FIG. 6B is different from the laser device 100B illustrated in FIG. 4 in that the iris 70 and the second mirror 10b are integrated with each other. As long as a part of a reflecting surface of the second mirror 10b is exposed by the opening 72 of the iris 70, the laser device 120B operates in the same manner as the laser device 100B.

### Seventh Modified Example

FIG. 6C is a top view schematically illustrating the configuration of the seventh modified example of the laser device according to the second embodiment. A laser device 130B illustrated in FIG. 6C is different from the laser device 100B illustrated in FIG. 4 in that the laser device 130B does not include the iris 70. Instead, the dimensions in the XY plane of the second mirror 10b2 illustrated in FIG. 6C is approximately the same as the dimensions in the XY plane of the opening 72 of the iris 70 illustrated in FIG. 4. Because the second mirror 10b2 plays a role as a mirror forming the resonator and as an iris, the laser device 100B can operate in the same manner as the laser device 100B. The minimum diameter of the reflecting surface of the second mirror 10b2 is, for example, at least one times the beam diameter of each of the light rays 20L, and the maximum diameter of the reflecting surface of the second mirror 10b2 is, for example, less than twice the beam diameter of each of the light beams 20 L.

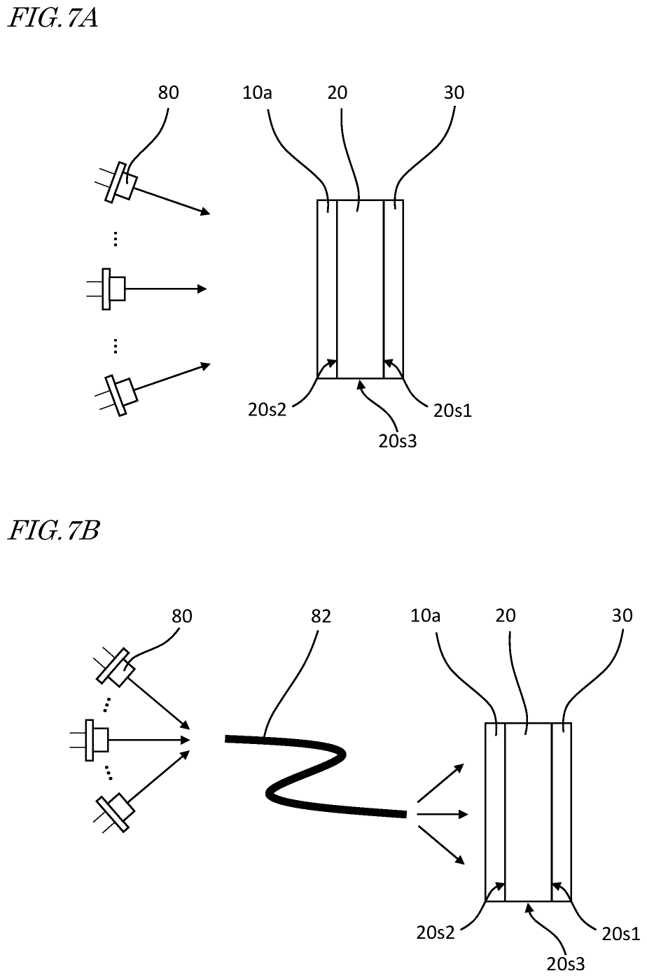

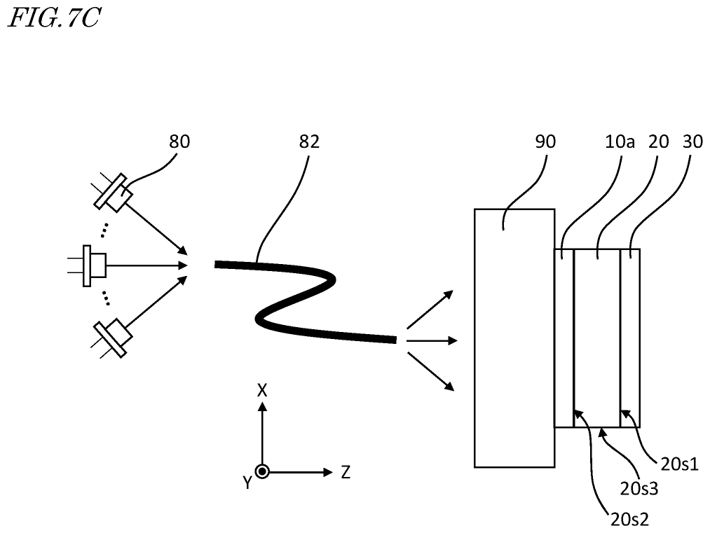

Method of Optically Exciting Gain Medium 20 in First and Second Embodiments Examples of optically exciting the gain medium 20 in the first embodiment and the second embodiment are described below with reference to FIGS. 7A to 7C. FIG. 7A is a top view schematically illustrating a first example of optically exciting the gain medium 20. The laser device 100A according to the first embodiment and the laser device 100B according to the second embodiment each include at least one light source 80 that emits excitation light toward the back surface 20s2, which is located on an opposite side of the gain medium 20 from the light emitting surface 20s1, or toward a lateral surface 20s3 of the gain medium 20. The laser device 100A according to the first embodiment and the laser device 100B according to the second embodiment each include a plurality of light sources 80 that emit excitation light toward the back face 20s2 of the gain medium 20. The straight arrow illustrated in FIG. 7A represents the excitation light emitted from each light source 80. The light source 80 may be, for example, an LD or an LED. A single light source 80 may be used instead of the plurality of light sources 80. The entire back surface 20s2 may be uniformly irradiated with the excitation light emitted from the plurality of light sources 80, or a partial region of the back surface 20s2 may be irradiated. Employing the uniform irradiation of the entire surface of the back surface 20s2 can extract a high-power laser beam compared to a case in which a partial region of the back surface 20s2 is irradiated. The gain medium 20 includes the lateral surface 20s3 in addition to the light emitting surface 20s1 and the back surface 20s2. The plurality of light sources 80 may emit excitation light toward the light emitting surface 20s1 or the lateral surface 20s3 of the gain medium 20.

FIG. 7B is a top view schematically illustrating a second example of optically exciting the gain medium 20. The laser device 100A according to the first embodiment and the laser device 100B according to the second embodiment each include an optical fiber 82 that allows excitation light emitted from the plurality of light 80 to propagate therethrough and the excitation light to exit toward the back surface 20s2 or the lateral surface 20s3 of the gain medium 20, in addition to the plurality of light sources 80. Preferably, the back surface 20s2 of the gain medium 20 is irradiated with the excitation light focused by the optical fiber 82. Because the output of the excitation light is increased compared to a case in which the gain medium 20 is excited by each of the plurality of light sources 80, the gain medium 20 can be excited more strongly. Thus, light emitted when the gain medium 20 is excited becomes strong, so a high-power laser beam can be extracted from the laser devices 100A and 100B. When the back surface 20s2 of the gain medium 20 is irradiated with the excitation light focused by the optical fiber 82, the output of a laser beam extracted is increased compared to a case in which the light emitting surface 20s1 or the lateral surface 20s3 of the gain medium 20 is irradiated.

FIG. 7C is a top view schematically illustrating a third example of optically exciting the gain medium 20. The laser device 100A according to the first embodiment and the laser device 100B according to the second embodiment each include a heat sink 90 in thermal contact with the back surface 20s2 of the gain medium 20, in addition to the plurality of light sources 80 and the optical fiber 82. The heat sink 90 can efficiently transmit heat generated by the gain medium 20 to the outside when the laser devices 100A and 100B are driven. Thermal conductivity of the heat sink 90 may be in a range from 10 W/m·K to 800 W/m·K, for example.

Because the dimension in the Z direction of the gain medium 20 is small, the heat generated by the gain medium 20 can be efficiently transmitted to the heat sink 90, to thereby make it possible to suppress a thermal lens effect in the gain medium 20 and to stabilize resonance.

When the back surface 20s2 of the gain medium 20 is irradiated with excitation light focused by the optical fiber 82, the heat sink 90 is formed from a material having thermal conductivity and transmissivity with respect to the excitation light. Such a material may be, for example, MN or diamond.

When the light emitting surface 20s1 or the lateral surface 20s3 of the gain medium 20 is irradiated with excitation light focused by the optical fiber 82, the heat sink 90 may also be formed from a material having thermal conductivity but having no transmissivity with respect to the excitation light. Such a material may be, for example, copper, or composites of metal and diamond.

Note that the gain medium 20 may be excited by current injection. In such a case, the gain medium 20 includes, in addition to an active layer, a p-type cladding layer and a n-type cladding layer interposing the active layer therebetween in the Z direction, and a p-side electrode and an n-side electrode respectively electrically connected to the p-type cladding layer and the n-type cladding layer. The gain medium 20 can be excited by injecting forward current into the gain medium 20 via the p-side electrode and the n-side electrode.

The laser devices of the present disclosure are applicable to industrial fields where high-power laser sources are needed, for example, cutting, drilling, local heat treatment, surface treatment, welding of metal, 3D printing, and the like of various materials.

What is claimed is:

1. A laser device comprising:
a first mirror and a second mirror forming a resonator;
a gain medium having a light emitting surface and disposed between the first mirror and the second mirror;
an antireflection film located on the light emitting surface of the gain medium;
an optical element disposed between the gain medium and the second mirror; and
a diffraction grating disposed between the optical element and the second mirror, wherein:
the gain medium is a semiconductor layered body comprising an active layer and having a varying gain distribution in at least a first direction within the light emitting surface, and
the gain medium comprises no waveguide.

2. The laser device according to claim 1, wherein a wavelength at which a gain is maximized in the gain medium varies so that the wavelength becomes shorter from a first end of the gain medium to a second end of the gain medium along the first direction within the light emitting surface.

3. The laser device according to claim 1, wherein the active layer comprises a nitride semiconductor containing indium and/or aluminum, and
a content of the indium and/or aluminum in the nitride semiconductor varies in the light emitting surface.

4. The laser device according to claim 1, wherein:
light extracted outward from the resonator comprises a plurality of light rays, and
peak wavelengths of the plurality of light rays vary monotonically along the one direction on the light emitting surface of the gain medium.

5. The laser device according to claim 4, wherein the peak wavelengths of the plurality of light rays are in a range from 350 nm to 550 nm.

6. The laser device according to claim 1, wherein:
the second mirror is a concave mirror, and
the gain medium is disposed so that a distance between the light emitting surface of the gain medium and a principal point of the optical element is shorter than a focal length of the optical element.

7. The laser device according to claim 1, further comprising a Brewster window disposed between the diffraction grating and the second mirror.

8. The laser device according to claim 1, further comprising a light source configured to emit excitation light toward a back surface of the gain medium, opposite the light emitting surface, or toward a lateral surface of the gain medium.

9. The laser device according to claim 8, further comprising an optical fiber configured to allow the excitation light to propagate and exit toward the back surface or the lateral surface of the gain medium.

10. The laser device according to claim 1, further comprising a heat sink in thermal contact with a back surface of the gain medium opposite the light emitting surface.

11. The laser device according to claim 1, wherein:
the optical element comprises a lens array, and an additional diffraction grating,
the lens array comprises a plurality of collimating units and a plurality of link portions linking the plurality of collimating units,
the diffraction grating is disposed parallel to the additional diffraction grating between the lens array and the second mirror, and
the laser device comprises an iris between the diffraction grating and the second mirror,
the additional diffraction grating diffracts light from the gain medium to the second diffraction grating, and
the diffraction grating combines the light diffracted by the additional diffraction grating and diffracts the combined light to the second mirror.

12. A laser device comprising:
a first mirror and a second mirror forming a resonator;
a gain medium having a light emitting surface and disposed between the first mirror and the second mirror;
an antireflection film located on the light emitting surface of the gain medium;
an optical element disposed between the gain medium and the second mirror; and
a diffraction grating disposed between the optical element and the second mirror, wherein:
the gain medium is a semiconductor layered body comprising an active layer and having a varying gain distribution in at least a first direction within the light emitting surface, and
the gain medium is a surface emitting light source.
